(19) United States
(12) Patent Application Publication
(10) Pub. No.: US 2012/0117925 A1
(43) Pub. Date: May 17, 2012

(54) APPARATUS AND METHOD FOR PACKAGING CHIP COMPONENTS

(75) Inventor: Hiroyuki ITOU, Tokyo (JP)

(73) Assignee: LAPIS Semiconductor Co., Ltd., Tokyo (JP)

(21) Appl. No.: 13/297,034

(22) Filed: Nov. 15, 2011

(30) Foreign Application Priority Data
Nov. 16, 2010 (JP) 2010-255828

(51) Int. Cl. H05K 13/00; B32B 3/00; B65B 51/00; B65B 5/08; B65B 15/04

(52) U.S. Cl. 53/471; 53/282; 53/329; 428/195.1

(57) ABSTRACT

A chip component packaging arrangement prevents occurrence of defective loading of chip components during a taping process that is carried out to the package chip components. This arrangement has a small size. A cover tape is prepared having a base tape and a plurality of cover film pieces sequentially attached to the base tape. Each cover film piece has an adhesive part. The cover tape extends in a direction intersecting a longitudinal direction of a carrier tape. The carrier tape has a plurality of component receiving parts sequentially formed in its longitudinal direction. The cover tape is pressed to the carrier tape so that one of the cover film pieces is adhered to the carrier tape to seal the corresponding component receiving part.

### FIELD OF THE INVENTION

The present invention relates to a chip component packaging apparatus adapted to package chip components by a taping process. The present invention also relates to a method for packaging chip components. The present invention further relates to a cover tape used when packaging chip components.

### DESCRIPTION OF RELATED ART

Manufactured chip components, such as semiconductor integrated circuit (IC) chips, are subjected to a product test, are packaged in a predetermined package form and are shipped. A chip component packaging apparatus is adapted to place a plurality of chip components in a plurality of recesses (i.e., concaves to receive chip components) formed in a carrier tape, respectively, and to close open tops of the recesses using a cover tape. Such apparatus is, for example, disclosed in FIGS. 1 and 5 of Japanese Patent Application Publication (Kokai) No. 2003-200905. In this packaging apparatus, each chip component (6) is conveyed into a corresponding recess or component receiving part (4) of a carrier tape (2) by a conveyance module (8). Upon carrying a predetermined number of chip components into the component receiving parts of the carrier tape, a cover tape is fused to the surface of the carrier tape at a fusing start position while the carrier tape is moving, thereby encapsulating the chip components in the component receiving parts. This packaging apparatus requires a certain distance between the fusing start position of the cover tape and the conveyance module in order to ensure that the conveyance module does not interfere with the cover tape. Thus, when the carrier tape moves from the conveyance module to the fusing start position, the chip components may vibrate, tilt, turn and/or escape from the component receiving parts. In order to avoid these defects in positioning of the chip components, the packaging apparatus has a pressing cover over or above the carrier tape (see reference numeral (14) in FIG. 4 of Japanese Patent Application Publication No. 2003-200905).

Since the pressing cover is spaced slightly from the carrier tape so as not to come into contact with the carrier tape, however, the chip components may still be able to turn and incline in the component receiving parts due to intermittent feeding of the carrier tape and/or vibrations of the apparatus. In other words, positional defects of the chip components may occur.

### SUMMARY OF THE INVENTION

One object of the present invention is to provide a chip component packaging apparatus that is capable of preventing occurrence of positional defects of chip components during encapsulation of the chip components in component receiving parts (i.e., recesses).

Another object of the present invention is to provide a chip component packaging method that prevents the occurrence of positional defects of chip components during encapsulation of the chip components in the component receiving parts.

Still another object of the present invention is to provide a cover tape that is used in the taping process and that is capable of preventing the occurrence of positional defects of chip components during encapsulation of the chip components in the component receiving parts.

According to one aspect of the present invention, there is provided a chip component packaging apparatus adapted to load chip components respectively in a plurality of component receiving parts formed in a carrier tape and to encapsulate (or seal) the component receiving parts using a plurality of cover film pieces. The component receiving parts may be a plurality of recesses. The chip component packaging apparatus includes a carrier tape feeding mechanism to feed the carrier tape such that the component receiving parts are sequentially moved to a predetermined loading position at which each of the chip components is loaded in a corresponding one of the component receiving parts upon every feeding. The chip component packaging apparatus also includes a chip component loading unit to load each of the chip components in a corresponding one of the component receiving parts at the loading position. The chip component packaging apparatus also includes a cover tape feeding mechanism to feed a cover tape in a direction intersecting the carrier tape such that the cover tape faces the component receiving parts of the carrier tape. A plurality of cover film pieces are sequentially attached to the surface of the cover tape. Each cover film piece has an adhesive part. The chip component packaging apparatus also includes a pressing part to press the cover tape against the surface of the carrier tape so that the cover film pieces are adhered to the surface of the carrier tape to seal the component receiving parts.

According to another aspect of the present invention, there is provided a chip component packaging method for loading chip components respectively in a plurality of component receiving parts formed in a carrier tape and to seal the component receiving parts using a cover film. The component receiving parts may be recesses. The chip component packaging method includes the step of feeding the carrier tape such that each of the component receiving parts is located at a predetermined loading position upon every feeding. The method also includes the step of loading each of the chip components in a corresponding one of the component receiving parts at the loading position. The method also includes the step of feeding a cover tape in a direction intersecting the carrier tape suck that the surface of the cover tape faces the component receiving parts of the carrier tape. A plurality of cover film pieces are attached to the surface of the cover tape. Each cover film piece has an adhesive part. The method also includes the step of pressing the cover tape to the surface of the carrier tape such that the cover film pieces are adhered to the surface of the carrier tape to seal or encapsulate the component receiving parts. This pressing is carried out such that the cover film pieces are successively attached to the surface of the carrier tape, with part of one of each two adjacent cover film pieces overlapping a corresponding part of the other cover film piece.

According to still another aspect of the present invention, there is provided a cover tape including a plurality of quadrangular cover film pieces to encapsulate (or seal) a plurality of recesses or component receiving parts formed in a carrier tape. The cover film pieces are sequentially attached to a surface of the cover tape. An adhesive part is provided at each of the cover film pieces such that the adhesive part extends along three sides of the rectangular shape of the cover film piece.

As described above, a plurality of cover film pieces are sequentially attached to the cover tape, and the cover tape is disposed so as to extend in a direction intersecting the longitudinal direction of the carrier tape. The component receiving parts are sequentially formed in the carrier tape. By forcing the cover tape against the surface of the carrier tape, the cover film pieces are attached to the surface of the carrier tape to encapsulate (seal or close) openings of the respective component receiving parts.

Consequently, it is possible to reduce the distance from the chip component loading position to the chip component encapsulating position (or the recess sealing position). This reduces or eliminates positional defects of the chip components in the component receiving parts due to vibrations caused during feeding of the carrier tape from the loading position to the encapsulating position, and allows use of a small-size chip component encapsulating apparatus.

These and other objects, aspects and advantages of the present invention will become apparent to those skilled in the art from the following detailed description when read and understood in conjunction with the appended claims and drawings.

### BRIEF DESCRIPTION OF THE DRAWINGS

FIG. 1 illustrates a schematic view of a chip component packaging apparatus, depicted partly in cross section, according to one embodiment of the present invention when the chip component packaging apparatus is viewed from one side thereof;

FIG. 2 is a perspective view of the chip component packaging apparatus shown in FIG. 1 when the chip component packaging apparatus is viewed in the direction indicated by the white arrow of FIG. 1;

FIG. 3A illustrates a top view of a carrier tape used for the packaging apparatus shown in FIG. 1;

FIG. 3B illustrates a cross-sectional view of the carrier tape of FIG. 3A, taken along the centerline of the carrier tape;

FIG. 4A illustrates a bottom view of a cover tape used in a cover tape feeding mechanism shown in FIG. 1;

FIG. 4B shows a side view of the cover tape;

FIG. 5 shows a flow chart of a process to load and encapsulate chip components performed by a controller shown in FIG. 1;

FIGS. 6A to 6D and FIGS. 7E to 7H are a series of views to illustrate a series of actions carried out by the chip component packaging apparatus of FIG. 1 in the process of loading and encapsulating chip components;

FIG. 8A shows a top view of the carrier tape after chip packaging is finished;

FIG. 8B illustrates a cross-sectional view of the carrier tape taken along a center line of the carrier tape after the chip packaging is finished:

FIG. 9 illustrates a schematic lateral view of a chip component packaging apparatus according to another embodiment of the present invention, partly illustrated in cross section;

FIG. 10 is a flow chart showing a process of loading and encapsulating chip components performed by a controller shown in FIG. 9; and

FIGS. 11A to 11D and FIGS. 12E to 12H are a series of views to illustrate a series of actions carried out by the chip component packaging apparatus of FIG. 9 in the loading and encapsulating process.

### DETAILED DESCRIPTION OF THE INVENTION

In a chip component packaging apparatus according to an exemplary embodiment of the present invention, a plurality of cover film pieces are sequentially attached to a cover tape at predetermined intervals, and the cover tape intersects a carrier tape. The cover tape includes a plurality of cover film pieces. Each cover film piece has an adhesive portion. The carrier tape has a plurality of recesses or component receiving parts sequentially arranged along the length of the carrier tape. When the cover tape is pressed to the surface of the carrier tape, the cover film pieces attached to the cover tape are adhered to the surface of the carrier tape to encapsulate or seal the component receiving parts.

### EMBODIMENT 1

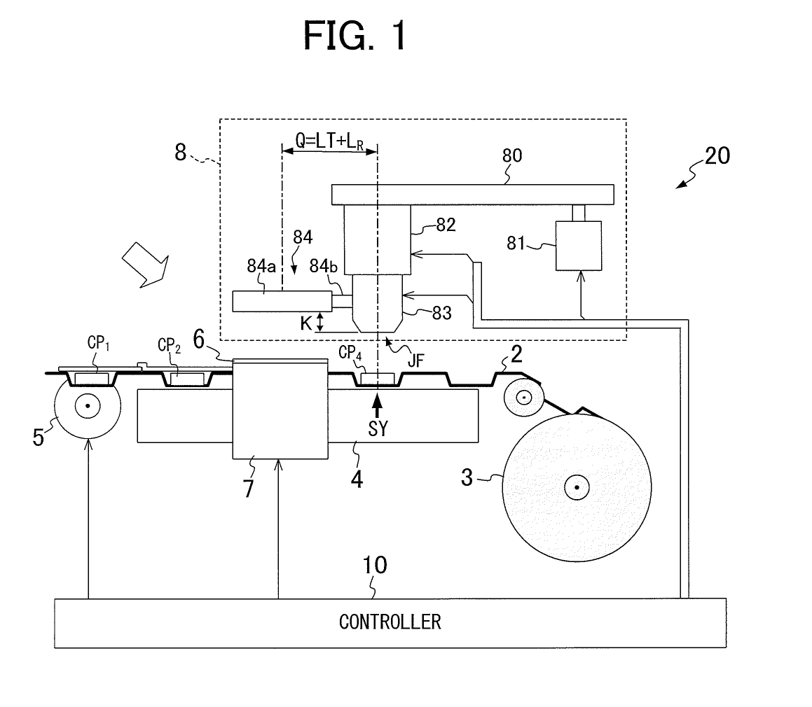

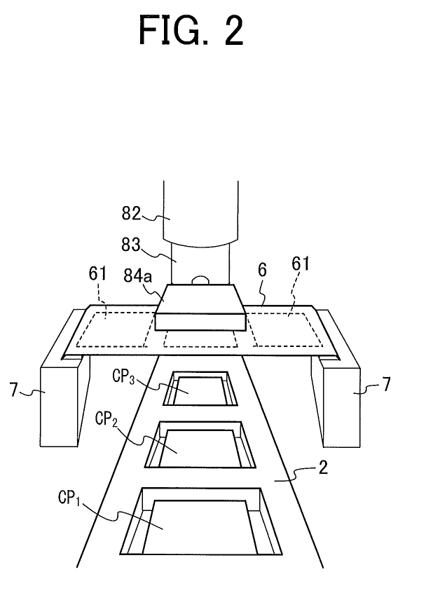

Referring to FIGS. 1 and 2, a chip component packaging apparatus 20 according to one embodiment of the present invention will be described.

The chip component packaging apparatus 20 shown in FIGS. 1 and 2 includes a reel 3 on which a carrier tape 2 is wound, a working stage 4, a carrier tape feeding mechanism 5, a cover tape feeding mechanism 7 to feed a cover tape 6, a loading and encapsulation unit 8 and a controller 10.

FIGS. 1 and 2 show the carrier tape 2 and the cover tape 5 placed in the chip component packaging apparatus 20. In FIGS. 1 and 2, chip components CP₁ and CP₂ have been loaded and encapsulated in the carrier tape 2, a chip component CP₃ is ready to be encapsulated in the carrier tape 2 and a chip component CP₄ is just loaded in the carrier tape 2. It should be noted that cover film pieces 61 over the chip components CP₁ and CP₂ are omitted in FIG. 2.

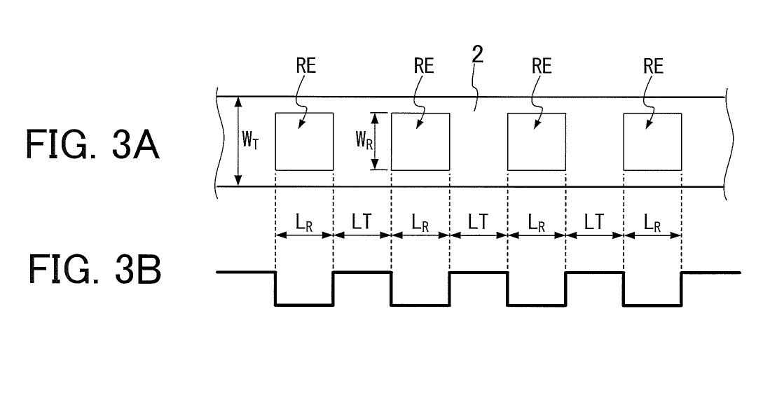

The carrier tape feeding mechanism 5 intermittently unwinds the carrier tape 2 from the reel 3 and intermittently feeds the carrier tape 2 onto the working stage 4 in response to a control signal supplied from the controller 10. The structure of the carrier tape 2 is shown in FIGS. 3A and 3B. The tape feeding direction is the same as the length direction of the tape 2. It should be noted that cover film pieces 61 are omitted over the chip components CP1 and CP2 in FIG. 2.

FIG. 3A depicts the carrier tape 2 on the working stage 4 when the carrier tape 2 is viewed from the top, and FIG. 3B is a cross-sectional view of the carrier tape 2 taken along the centerline of the carrier tape 2. The carrier tape 2 is made of resin. As shown in FIGS. 3A and 3B, a plurality of recesses or component receiving parts RE to receive a plurality of chip components is formed in the carrier tape 2 in a line at predetermined intervals LT in the longitudinal direction of the carrier tape 2. Each of the component receiving parts RE has a depth greater than a height of each chip component CP to be packaged. Each of the component receiving parts RE has a width W_{R} less than a tape width W_{T} of the carrier tape 2. Each of the component receiving parts RE has a length L_{R} in the longitudinal direction of the carrier tape 2. Each of the component receiving parts RE has an upper opening to receive one chip component CP.

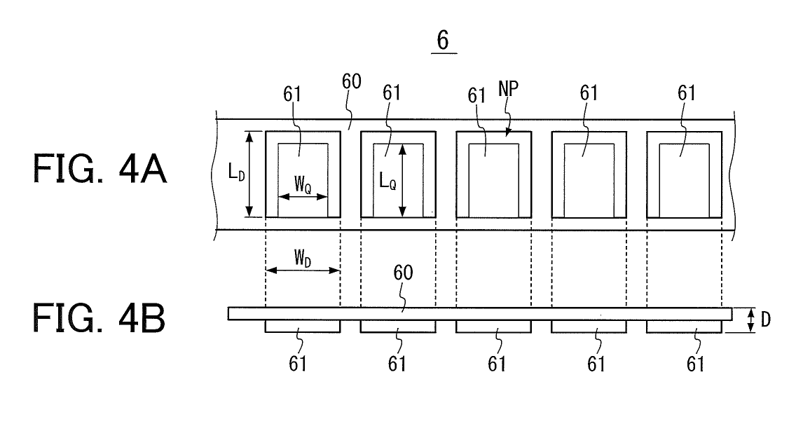

Referring back to FIG. 2, the cover tape feeding mechanism 7 feeds the cover tape 6 in the direction perpendicular to the longitudinal direction of the carrier tape 2 so that the cover tape 6 spans over the carrier tape in response to a control signal supplied from the controller 10. A slight gap is left between the top of the carrier tape 2 and the bottom of the cover tape 6 when the cover tape 6 extends over the carrier tape 2. The cover tape 6 has a structure as shown in FIGS. 4A and 4B.

FIG. 4A illustrates the cover tape 6 installed in the cover tape feeding mechanism 7 when the cover tape 6 is viewed from the bottom thereof, and FIG. 4B illustrates the cover tape 6 mounted in the cover tape feeding mechanism 7 when the cover tape 6 is viewed from one side thereof.

As shown in FIGS. 4A and 4B, the cover tape 6 includes a plurality of cover film pieces 61 attached to the bottom face of a mount tape (base tape) 60 in a line. The cover film pieces 61 are detachable from the mount tape 60. A width W_{D} of each cover film pieces 61 is greater than the width W_{R} of each component receiving part RE.

A length L_{D} of each cover film piece 61 is greater than a combined length of the length L_{R} of each component receiving part RE and the interval LT between the neighboring component receiving parts RE (i.e., L_{R}+LT) and is less than a sum of the above-mentioned combined length and a value equivalent to ½ of the interval LT (i.e., L_{R}+LT+0.5 LT). Therefore, it is possible to cause one end part of a later-provided cover film piece 61 to overlap a corresponding end part of the already-provided neighboring cover film piece 61 when the later-provided cover film piece 61 is adhered to the surface of the carrier tape 2.

L_{R}+LT<L_{D}

L_{R}+3·LT/2>L_{D}

Each cover film piece 61 has a rectangular shape having four sides when viewed from the bottom as shown in FIG. 4A. An inverted-U-shaped adhesive part NP is provided on the surface of each cover film piece 61 along the three sides of its rectangular shape excluding one side that extends along one of the two long sides of the cover tape 6. The adhesive part NP has adhesive power greater than attachment power of each of the cover film pieces 61 attached to the mount tape 60. It is possible to prevent each packaged chip component CP from being attached to the adhesive part NP of each of the cover film pieces 61 by setting a second width W_{Q} of each cover film piece 61 excluding the adhesive part NP to be equal to or greater than the width W_{R} of the component receiving part RE and setting a second length L_{Q} of each cover film piece 61 excluding the adhesive part NP to be equal to or greater than the length L_{R} of the component receiving part RE.

Referring back to FIG. 1, a plurality of chip components to be packaged is housed in a chip component storage (not shown). The loading and encapsulation unit 8 takes chip components from the chip component storage, and loads and encapsulates the chip components in the recesses RE of the carrier tape 2 in response to a control signal supplied from the controller 10.

The loading and encapsulation unit 8 has a conveyance arm 80, a conveyance arm drive motor 81, a vertical drive part 82, a suction nozzle 83 and a pressing part 84.

The conveyance arm drive motor 81 causes the conveyance arm 80 to turn to the chip component storage according to a control signal supplied from the controller 10, and one chip component is taken (suctioned) from the chip component storage by the suction nozzle 83. Then, the conveyance arm drive motor 81 causes the conveyance arm 80 to turn so that the suction nozzle 83 reaches a position above one of the component receiving parts RE of the carrier tape 2.

The vertical drive part 82, which is disposed on the conveyance arm 80, moves the suction nozzle 83 upward or downward according to a control signal supplied from the controller 10.

The suction nozzle 83 has a suction surface JF with a number of suction holes (not shown) through which a vacuum pump (not shown) suctions air. The suction nozzle 83 suctions one of the chip components housed in the chip component storage so that that chip component sticks to the suction surface JF according to a control signal supplied from the controller 10. When the suctioning operation of the suction nozzle 83 is stopped according to a control signal from the controller 10, the chip component falls downward from the suction surface JF. The pressing part 84 is coupled to the suction nozzle 83 to press each of the cover film pieces 61 to the carrier tape 2 via the mount tape 60.

The pressing part 84 includes a pressing plate 84a and a connection part 84b to connect the pressing plate 84a to the suction nozzle 83 such that the pressing plate 84a (or connection part 84b) extends parallel to the surface of the cover tape 6. It is preferable for the surface size of the pressing plate 84a to be greater than that of each cover film piece 61 so that the adhesive part NP of each cover film piece 61 is uniformly pressed against the carrier tape 2. The connection part 84b has a connection length such that the distance Q between the center of the pressing plate 84a and the center of the suction surface JF in the horizontal direction is equal to a sum of interval LT (FIG. 3B) between the component receiving parts RE (FIG. 3B) and the length L_{R} (FIG. 3B) of each component receiving part RE. The connection part 84b connects the pressing plate 84a to the suction nozzle 83 so that a vertical distance K between the bottom of the pressing plate 84a and the suction surface JF of the suction nozzle 83 is equal to or less than the thickness of the cover tape 6. When the suction nozzle 83 is positioned immediately above a loading position SY on the working stage 4 as shown in FIGS. 1 and 2, it is preferable for the connection part 84b to support the pressing plate 84a such that the pressing plate 84a is disposed immediately above the cover tape 6. With this configuration, the pressing plate 84a can press the surface of the cover tape 6 upon the downward movement of the suction nozzle 83 caused by the vertical drive part 82.

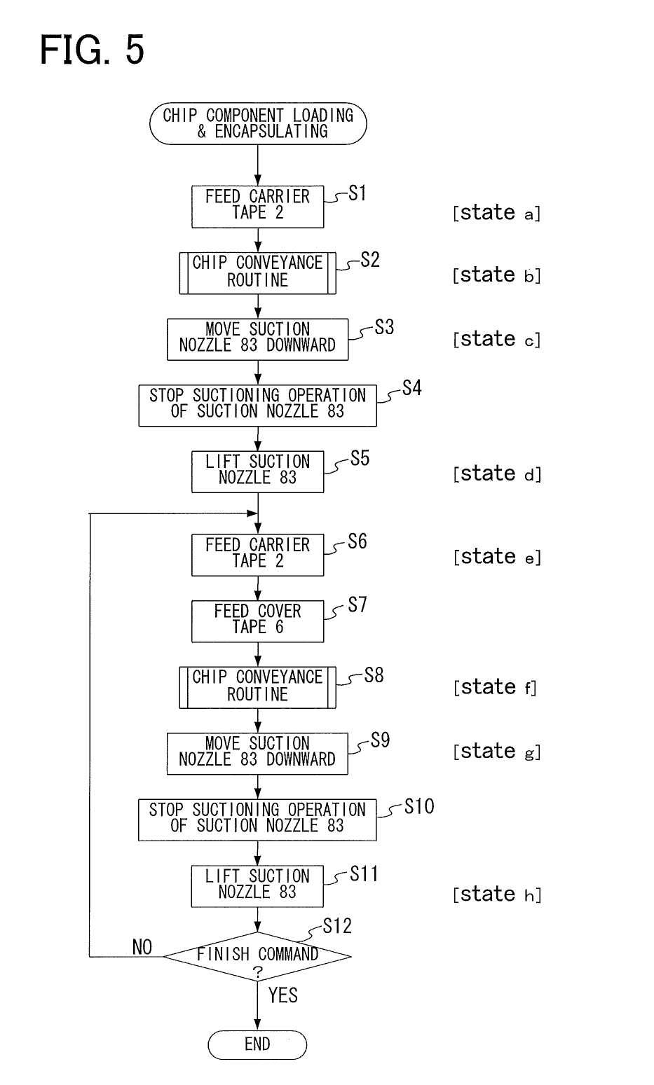

The controller 10 controls the operations of the carrier tape feeding mechanism 5, the cover tape feeding mechanism 7 and the loading and encapsulation unit 8 according to a flowchart shown in FIG. 5.

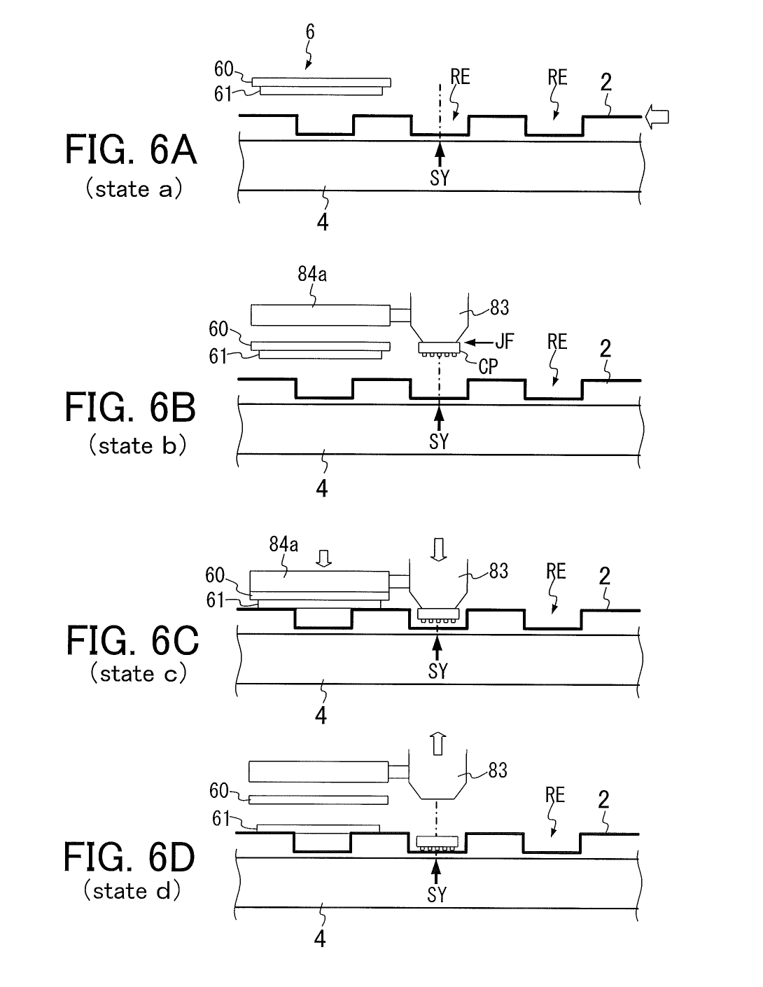

Referring to FIG. 5, first, the controller 10 controls the carrier tape feeding mechanism 5 to feed (unwinds) the carrier tape 2 from the reel 3 onto the working stage 4 until the center of one component receiving part RE of the carrier tape 2 reaches a position immediately above the loading position SY of the working stage 4 as shown in FIG. 6A (state a) (Step S1).

The controller 10 performs a chip conveyance control routine so that one of the chip components CP in the chip component storage is conveyed to the position immediately above the loading position SY of the working stage 4 as shown in FIG. 6B (state b) (Step S2). In the chip conveyance control routine, the controller 10 controls the conveyance arm drive motor 81 to move the loading and encapsulation unit 8 to the position of the chip component storage. When the loading and encapsulation unit 8 reaches the position of the chip component storage, the controller 10 causes the suction nozzle 83 to suction one of the chip components CP in the chip component storage so that the chip component CP is attached to the suction surface JF of the suction nozzle 83. After that, the controller 10 causes the conveyance arm drive motor 81 to move the suction nozzle 83 to the position immediately above the loading position SY as shown in FIG. 6B (state b).

When the suction nozzle 83 reaches the position immediately above the loading position SY, the controller causes the vertical drive part 82 to move the suction nozzle 83 downward until the suction surface JF of the suction nozzle 83 reaches a height equal to the top of the carrier tape 2, excluding the component receiving parts RE, as shown in FIG. 6C (state c) (Step S3).

When the suction surface JF of the suction nozzle 83 reaches the same height as the top of the carrier tape 2 as shown in FIG. 6C (state c), the controller 10 stops the suctioning operation performed by the suction nozzle 83 (Step S4). Subsequently, the controller 10 causes the vertical drive part 82 to move the suction nozzle 83 upward (Step S5).

As the result of the execution of Step S4, the chip component CP suctioned by the suction nozzle 83 falls downward and is loaded in a corresponding one of the component receiving parts RE of the carrier tape 2 as shown in FIG. 6D (state d).

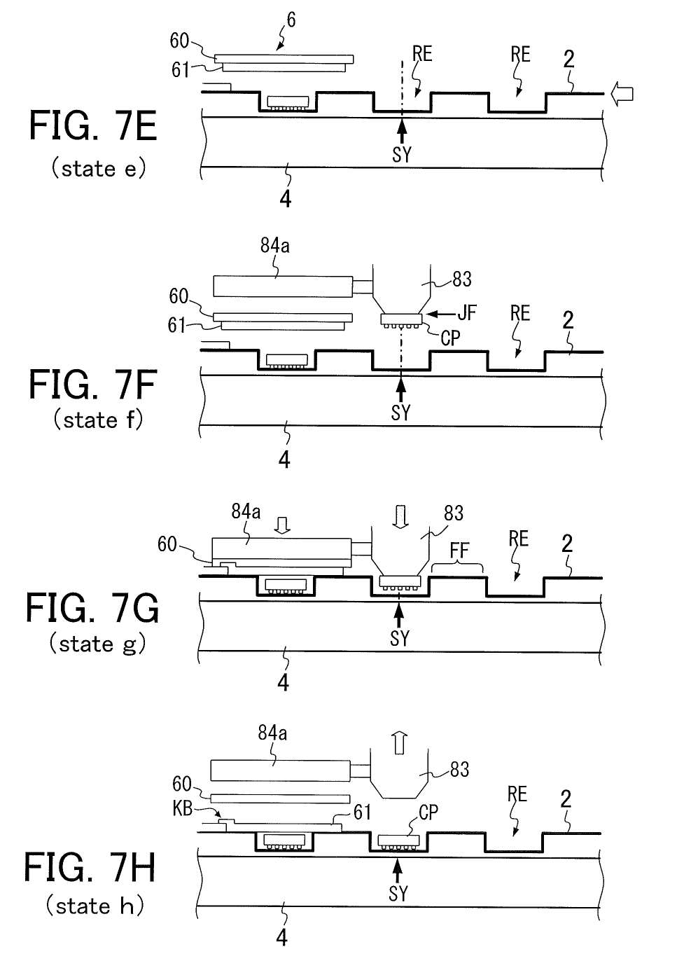

The controller 10 causes the carrier tape feeding mechanism 5 to feed the carrier tape 2 until the center of a vacant (or next) component receiving part RE adjacent to the component receiving part RE having the chip component CP loaded therein reaches a position immediately above the loading position SY of the working stage 4, as shown in FIG. 7E (state e) (Step S6).

The controller 10 causes the cover tape feeding mechanism 7 to feed one of the cover film pieces 61 attached to the cover tape 6 to a position immediately above a corresponding one of the component receiving parts RE of the carrier tape 2 as shown in FIG. 2 (Step S7).

The controller 10 performs a chip conveyance control routine so that one of the chip components CP in the chip component storage is conveyed to the position immediately above the loading position SY of the working stage 4 as shown in FIG. 7F (state f) (Step S8). The chip conveyance control routine performed at Step S8 is identical to that performed at Step S2, and therefore, a detailed description thereof is omitted. When the suction nozzle 83 reaches the position immediately above the loading position SY, the controller 10 causes the vertical drive part 82 to move the suction nozzle 83 downward until the suction surface JF of the suction nozzle 83 reaches a height equal to the top of the carrier tape 2, excluding the component receiving parts RE, as shown in FIG. 7G (state g) (Step S9).

When the suction surface JF of the suction nozzle 83 reaches the height equal to the top FF of the carrier tape as shown in FIG. 7G (state g), the pressing plate 84a connected to the suction nozzle 83 presses the cover tape 6 downward.

The pressing plate 84a is disposed above the suction surface JF of the suction nozzle 83 by a distance K (FIG. 1) equal to or less than the thickness D (FIG. 14) of the cover tape 6 (the sum of the thickness of the mount tape and the thickness of the cover film piece 61). Consequently, when the suction nozzle 83 is moved downward and the suction surface JF of the suction nozzle 83 reaches a height equal to the top FF of the carrier tape 2 as shown in FIG. 7G (state g), the pressing plate 84a presses the cover tape 6 to the top of the carrier tape 2. As a result, the adhesive part NP of the cover film piece of the cover tape 6 is pressed to the outer circumferential region of a corresponding one of the component receiving parts RE of the carrier tape 2, and therefore, the cover film piece 61 is adhered to the top of the carrier tape 2 to cover (or close or seal) the opening of the component receiving part RE.

When the suction nozzle 83 is moved downward and the suction surface JF of the suction nozzle 83 reaches the height equal to the top FF of the carrier tape 2, the controller 10 stops the suctioning operation performed by the suction nozzle 83 (Step S10).

As the result of the execution of Step S10, the chip component CP falls from the suction nozzle 83 downward into a corresponding one of the component receiving parts RE of the carrier tape 2. In other words, the chip component CP is loaded in the component receiving part RE of the carrier tape 2.

After the execution of Step S10, the controller 10 causes the vertical drive part 82 to move the suction nozzle 83 upward (Step S11).

As the result of the execution of Step S11, the pressing plate 84a, which is pressing the cover tape 6 to the carrier tape 2, is separated from the cover tape 6. The adhesive power of the adhesive part NP of the cover film piece 61 is greater than the attachment power of the cover film piece 61 attached to the mount tape 60. When the pressing plate 84a is separated from the cover tape 6, therefore, the cover film piece 61 is separated from the mount tape 60 as shown in FIG. 7H (state h). Thus, only the cover film piece 61 is adhered to the top of the carrier tape 2 to cover (seal) the opening of the component receiving part RE. That is, the chip component CP is encapsulated in the component receiving part RE by the cover film piece 61.

The controller 10 determines whether an operation end instruction has been supplied (Step S12). Upon determining that the operation end instruction has been supplied at Step S12, the controller 10 ends the process of controlling loading and encapsulation of the chip components shown in FIG. 5. That is, the loading and encapsulation operation of the chip components performed by the chip component packaging apparatus 20 shown in FIG. 1 ends. On the other hand, upon determining that the operation end instruction has not been supplied at Step S12, the procedure returns to Step S6 and the controller 10 repeats Steps S6 to S11.

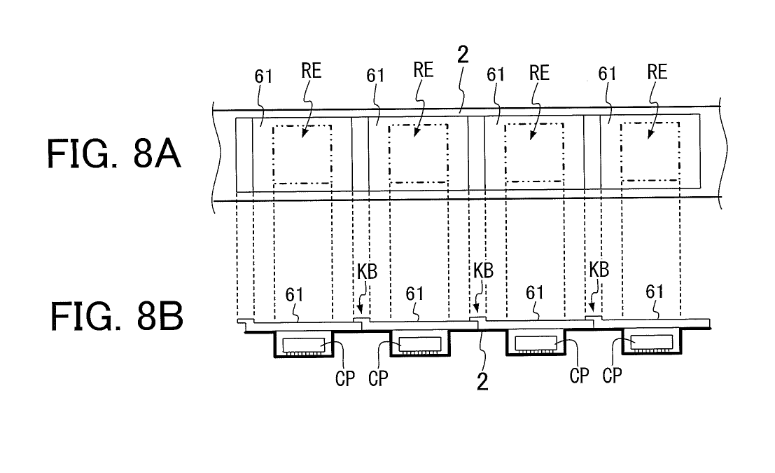

That is, the operations shown in FIG. 7E (state e) to FIG. 7H (state h) are repeated and, as shown in FIGS. 8A and 8B, the chip components CP are sequentially loaded in the respective component receiving parts RE of the carrier tape 2. In addition, the chip components CP are individually encapsulated by the respective cover film pieces 61. FIG. 8A shows the carrier tape 2 when the carrier tape 2 is viewed from the top thereof after the chip components CP are loaded and encapsulated and FIG. 8B depicts a cross-sectional view of the carrier tape 2. In the encapsulating process, corresponding ends of neighboring cover film pieces 61 overlap each other as indicated by overlap parts KB in FIG. 8B (or FIG. 7G). When a user wants to take a plurality of chip components CP out of the carrier tape 2 after the encapsulation process, therefore, it is possible to continuously peel the cover film pieces 61 from the carrier tape 2 until the overlapping parts KB break apart or until the user stops the peeling, whichever comes earlier. Consequently, it is possible to quickly take out two or more chip components. It should be noted that it is also possible to peel the cover film piece 61 one piece by one piece if a user wants so.

In the chip component packaging apparatus 20 shown in FIG. 1, the cover tape 6 includes the cover film pieces 61 attached to the bottom of the mount tape 60 in a line. The adhesive part NP is provided along the outer circumferential region of each of the cover film pieces 61, as shown in FIGS. 4A and 4B. The cover tape 6 is disposed above the carrier tape 2 such that the cover tape 6 extends in the direction intersecting the longitudinal direction of the carrier tape 2 as shown in FIG. 2. The cover tape 6 is pressed downward onto the top of the carrier tape 2, and the respective component receiving parts RE are individually encapsulated by the cover film pieces 61. According to this construction, it is possible to install the cover tape feeding mechanism 7 in the vicinity of the chip component loading position SY, with the cover tape 6 extending in the perpendicular direction to the longitudinal direction of the carrier tape 2 as shown in FIG. 1.

Consequently, it is possible to reduce the distance from the chip component loading position SY (i.e., the location of one of the component receiving parts RE to receive a chip component CP in question) on the working stage 4 to the encapsulating position at which that chip component CP is encapsulated (i.e., below the cover tape 6). Therefore, it is possible to reduce the size of the apparatus 20. In addition, it is possible to reduce or eliminate positional defects of the chip components due to vibration caused during feeding of the carrier tape 2 from the loading position SY to the encapsulating position.

Use of the cover tape 6 makes it possible to easily remove foreign matter from the component receiving parts RE after the encapsulating process (or taping process). Use of the cover pate 6 also makes it possible to easily replace defective chip component after the encapsulating process. In other words, it facilitates a repair operation. This is mostly because provision of each cover film piece 61 onto the carrier tape 2 is implemented by a taping process. Each cover film piece 61 may be considered as a piece of tape. The cover film piece 61 adheres to the carrier tape 2 upon the pressing, and is relatively easy to peel after the pressing.

Conventionally, a long single cover tape is fused onto the carrier tape to seal all the chip component receiving recesses RE. When foreign matters are removed and/or defective chip components are replaced after the encapsulating process in the conventional art, this cover tape is partly peeled off to remove the foreign matter and/or exchange the defective chips. Then, the peeled portion of the cover tape is fused again to the carrier tape. Peeling the long cover tape, however, may damage the cover tape and carrier tape. Chip replacement work and foreign matter removal work are not easy if the long single cover tape is fused to the carrier tape. According to the present invention, on the other hand, the cover tape 6 having a plurality of cover film pieces 61 is employed such that each cover film piece 61 seals each recess RE of the cover tape 2. Therefore, only those cover film pieces 61 which seal defective chip components CP are peeled off when replacing the defective chip components CP, and other cover film pieces 61 are not touched. Only those cover film pieces 61 which seal foreign matters together with chip components CP are peeled off when removing the foreign matters from those recesses RE. As such, it facilitates a repair/cleaning operation. The adhesive power of the cover film piece 61 is not too strong so that peeling one cover film piece 61 does not adversely affect an adjacent cover film piece 61. Replacement of the cover film piece 61 is also easy.

In the chip component packaging apparatus 20 shown in FIG. 1, the pressing part 84 to press the cover film piece 61 to the carrier tape 2 so that the cover film piece 61 is adhered to the top of the carrier tape 2 is provided at the main body of the suction nozzle 83 that is adapted to load the chip component CP in the component receiving part RE. Consequently, the pressing part 84 presses the cover film piece 61 to the carrier tape 2 upon the downward movement of the suction nozzle 83 for the loading of the chip component CP in the component receiving part RE.

As such, a separate drive unit for vertically moving the pressing part 84 is not necessary. This contributes to cost reduction and power consumption reduction for the component packaging apparatus 20.

### EMBODIMENT 2

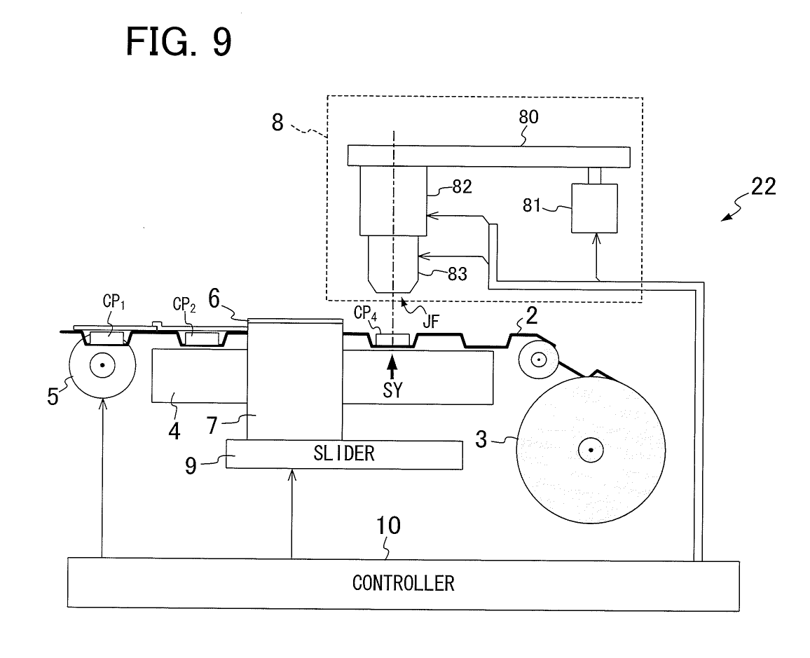

FIG. 9 illustrates a chip component packaging apparatus 22 according to another embodiment of the present invention when the chip component packaging apparatus 22 is viewed from one side thereof, with some portions being depicted in cross section.

The chip component packaging apparatus 22 shown in FIG. 9 is similar in construction to the chip component packaging apparatus 20 shown in FIG. 1 except that the pressing part 84 is dispensed with and a slider mechanism 9 is added. Similar reference numerals and symbols are used to designate similar parts and components in FIGS. 1 and 9.

The slider mechanism 9 shown in FIG. 9 horizontally moves the cover tape feeding mechanism 7 in the longitudinal direction of the carrier tape 2 according to a control signal supplied from the controller 10.

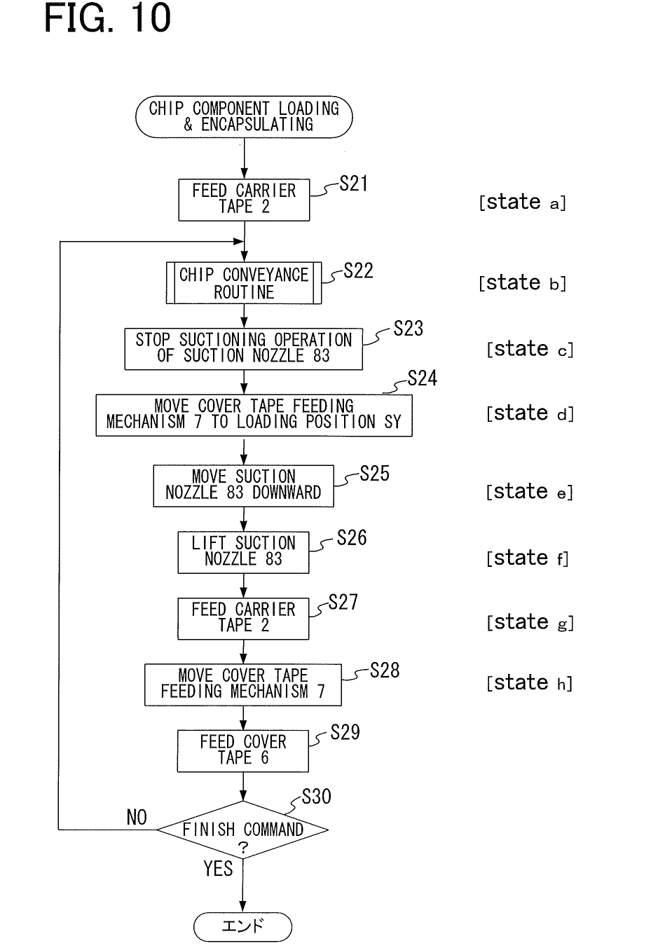

FIG. 10 is a flow chart showing a process to control loading and encapsulation of chip components performed by the chip component packaging apparatus 22 shown in FIG. 9.

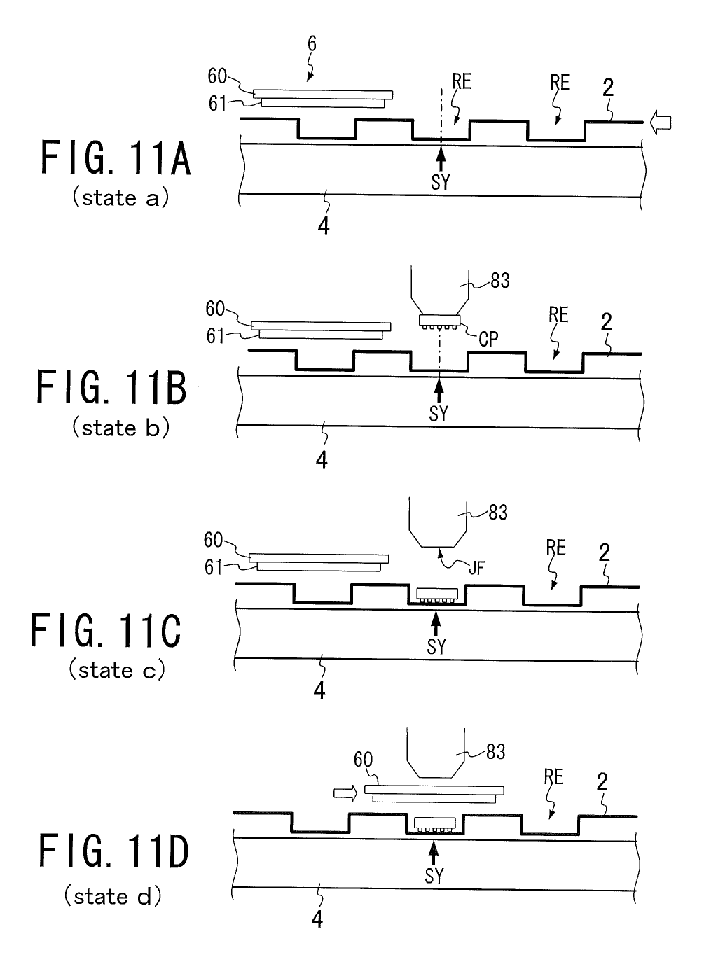

Referring to FIG. 10, first, the controller 10 causes the carrier tape feeding mechanism 5 to feed (unwinds) the carrier tape 2 from the reel 3 onto the working stage 4 until the center position of one of the component receiving parts RE in the carrier tape 2 reaches a position immediately above the loading position SY of the working stage 4 as shown in FIG. 11A (state a) (Step S21).

The controller 10 performs a chip conveyance control routine so that one of the chip components CP housed in the chip component storage (not shown) is conveyed to the position immediately above the loading position SY of the working stage 4 as shown in FIG. 11B (state b) (Step S22). In the chip conveyance control routine, the controller 10 causes the conveyance arm drive motor 81 to move the loading and encapsulation unit 8 toward the chip component storage. When the loading and encapsulation unit 8 reaches the chip component storage, the controller 10 causes the suction nozzle 83 to suction one of the chip components CP in the chip component storage so that the chip component CP is attached to the suction surface JF of the suction nozzle 83. Subsequently, the controller 10 causes the conveyance arm drive motor 81 to move the suction nozzle 83 to the position immediately above the loading position SY as shown in FIG. 11B (state b).

When the suction nozzle 83 reaches the position immediately above the loading position SY, the controller 10 stops the suctioning operation performed by the suction nozzle 83 (Step S23). As a result, the chip component CP falls from the suction nozzle 83 downward and is loaded in a corresponding one of the component receiving parts RE of the carrier tape 2 as shown in FIG. 11C (state c).

The controller 10 causes the slider mechanism 9 to move the cover tape feeding mechanism 7 toward the loading position SY (Step S24). As a result, the cover tape 6 is moved to a position immediately above the loading position SY as shown in FIG. 11D (state d).

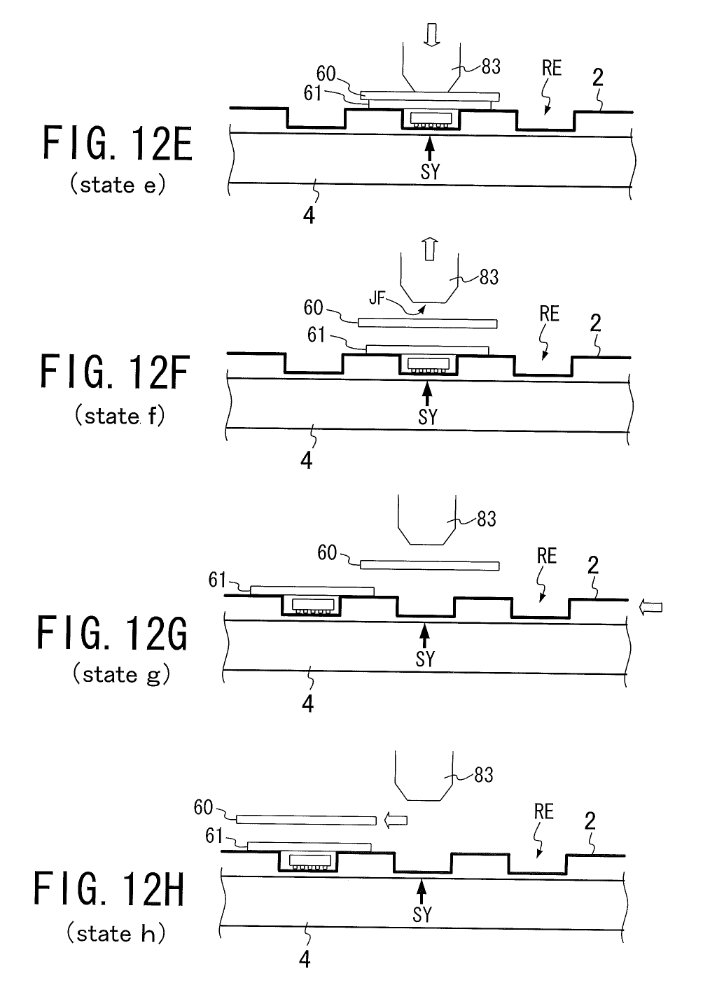

The controller 10 causes the vertical drive part 82 to move the suction nozzle 83 downward (Step S25). As a result, the suction surface JF of the suction nozzle 83 comes into contact with the top of the mount tape 60 of the cover tape 6 and the corresponding one of the cover film pieces 61 of the cover tape 6 is pressed to the top of the carrier tape 2 by the suction nozzle 83 as shown in FIG. 12E (state e). Since the adhesive part NP of the cover film piece 61 is pressed to the outer circumferential region of the component receiving part RE formed of the carrier tape 2, the cover film piece 61 is adhered to the carrier tape 2 to cover (seal) the opening of the component receiving part RE.

Then, the controller 10 causes the vertical drive part 82 to move the suction nozzle 83 upward as shown in FIG. 12F (state f) (Step S26). As a result, the suction nozzle 83 is separated from the top of the mount tape 60 of the cover tape 6. The adhesive power of the adhesive part NP of the cover film piece 61 is greater than the attachment power of the cover film piece 61 attached to the mount tape 60. When the pressing part 83 is separated from the cover tape 6, therefore, the cover film piece 61 is separated from the mount tape 60 as shown in FIG. 12F (state f) and only the cover film piece 61 remains on (or is adhered to) the top of the carrier tape 2 to cover the opening of the component receiving part RE. That is, the chip component CP is encapsulated in the component receiving part RE by the cover film piece 61.

The controller 10 causes the carrier tape feeding mechanism 5 to feed the carrier tape 2 until the center position of a vacant (or next) component receiving part RE adjacent to the component receiving part RE having the chip component CP loaded therein reaches a position immediately above the loading position SY of the working stage 4 as shown in FIG. 12G (state g) (Step S27).

The controller 10 causes the slider mechanism 9 to move the cover tape feeding mechanism 7 from the loading position SY to a predetermined waiting position (Step S28). As a result, the cover tape 6 is moved to a position apart from the loading position SY, i.e., a position at which loading of the (next) chip component CP performed by the suction nozzle 83 is not disturbed, as shown in FIG. 12H (state h).

The controller 10 causes the cover tape feeding mechanism 7 to feed one of the cover film pieces 61 attached to the cover tape 6 to a position immediately above a corresponding one of the component receiving parts RE of the carrier tape 2 as shown in FIG. 2 (Step S29).

The controller 10 determines whether an operation end instruction has been supplied (Step S30). Upon determining that the operation end instruction has been supplied at Step S30, the controller 10 ends the process of controlling the loading and encapsulation of the chip components shown in FIG. 10. That is, the chip component loading and encapsulation operation performed by the chip component packaging apparatus 22 shown in FIG. 9 is ended. On the other hand, upon determining that the operation end instruction has not been supplied at Step S20, the procedure returns to Step S22 and the controller 10 repeats Steps S22 to S20.

That is, the operations shown in FIGS. 11B to 11D and FIGS. 12E to 12H are repeated and, as shown in FIGS. 8A and 8B, chip components CP are sequentially loaded in the respective component receiving parts RE of the carrier tape 2 one by one. In addition, the chip components CP are individually encapsulated by the respective cover film pieces 61. In the encapsulating process, corresponding ends of neighboring cover film pieces 61 overlap each other as indicated by the overlap parts KB in FIG. 8B in the same manner as the chip component packaging apparatus 20 (FIG. 1) of the first embodiment. When a plurality of chip components CP is taken out of the carrier tape 2 after the encapsulation process, therefore, the cover film pieces 61 are continuously peeled off the carrier tape 2. Consequently, it is possible to quickly take out a large number of chip components CP.

In the chip component packaging apparatus 22 of the second embodiment, the cover tape 6 includes the cover film pieces 61 attached to the bottom of the mount tape 60 in a single line, and the adhesive part NP is provided along the outer circumferential region of each of the cover film pieces 61, as shown in FIGS. 4A and 4B, in the same manner as the chip component packaging apparatus 20 of the first embodiment. The cover tape 6 is disposed above the carrier tape 2 so that the cover tape 6 extends in the perpendicular direction to the longitudinal direction of the carrier tape 2 as shown in FIG. 2. The cover tape 6 is pressed downward to the top of the carrier tape 2, and the component receiving parts RE are individually encapsulated by the corresponding cover film pieces 61. In the chip component packaging apparatus 22 shown in FIG. 9, the cover film piece 61 of the cover tape 6 is pressed to the carrier tape 2 by the suction surface JF of the suction nozzle 83 as shown in FIG. 12E (state e). After the chip component CP is loaded in the component receiving part RE at the loading position SY in the chip component packaging apparatus 22, the slider mechanism 9 moves the cover tape to the loading position SY so that the encapsulation operation is performed at the loading position SY.

Consequently, the chip component CP is encapsulated at the loading position SY, i.e., at the same place for the chip component loading. Therefore, the carrier tape 2 is not moved from the loading of the chip component CP until completion of the encapsulating of the chip component CP. As a result, it is possible to prevent the occurrence of a positional defect of the chip component CP.

In the first and second embodiments, the nozzle 83 is used to grip (or hold) the chip component CP with the suctioning force. It should be noted, however, that the chip component CP may be gripped using techniques other than suction. Instead of the suctioning nozzle 83, for example, a structure or mechanism having a plurality of arms and/or claws to grip the side faces of the chip component CP may be adopted.

In the embodiments shown in FIGS. 1 and 9, the cover tape 6 is fed in the direction perpendicular to the carrier tape 2, with the cover tape 6 extending above the carrier tape 2 as shown in FIG. 2. It should be noted that the feeding direction of the cover tape 6 with respect to the carrier tape 2 is not limited to 90 degrees.

In the above-described embodiments, the cover film pieces 61 are sequentially attached to the lower surface of the mount tape 60 in a single line in the longitudinal direction of the cover tape 6 as shown in FIGS. 4A and 4B. Alternatively, the cover film pieces 61 may be sequentially attached in two or more lines.

This application is based on Japanese Patent Application No. 2010-255828 filed on Nov. 16, 2010, and the entire disclosure thereof is incorporated herein by reference.

What is claimed is:

1. A chip component packaging apparatus for loading a plurality of chip components in a plurality of component receiving parts formed in a carrier tape respectively and for encapsulating the component receiving parts using a plurality of cover film pieces, the chip component packaging apparatus comprising:
a carrier tape feeding mechanism to feed the carrier tape such that the component receiving parts are moved, upon each feeding operation, to a predetermined loading position at which each of the chip components is loaded in a corresponding one of the component receiving parts;
a chip component loading unit to load said each of the chip components in said corresponding one of the component receiving parts at the loading position;
a cover tape feeding mechanism to feed a cover tape in a direction intersecting the carrier tape such that the cover tape faces said corresponding one of the component receiving parts of the carrier tape;
a plurality of cover film pieces attached to the cover tape, each of the plurality of cover film pieces having an adhesive part; and
a pressing part to press the cover tape to the carrier tape such that one of the cover film pieces is forced to adhere to the carrier tape to encapsulate each said chip component in the corresponding one of the component receiving parts.

2. The chip component packaging apparatus according to claim 1, wherein each said the cover film piece has a quadrangular shape and the adhesive part extends along three sides of the quadrangular shape.

3. The chip component packaging apparatus according to claim 2, wherein a width of each said cover film piece is greater than a first sum of a length of each said component receiving part and an interval between two neighboring component receiving parts and is less than a second sum of a half of the interval and the first sum.

4. The chip component packaging apparatus according to claim 1, wherein the adhesive part has adhesive power greater than attachment power of each said cover film piece attached to the cover tape.

5. The chip component packaging apparatus according to claim 1, wherein the chip component loading unit has a gripping part to grip each said chip component and a vertical drive part to move the gripping part upward and downward, and the pressing part is supported by the gripping part such that the cover tape is pressed to the carrier tape according to a movement of the gripping part caused by the vertical drive part.

6. The chip component packaging apparatus according to claim 5, wherein the gripping part and the pressing part are spaced apart from each other by a distance corresponding to an interval between two neighboring component receiving parts.

7. The chip component packaging apparatus according to claim 1, wherein said plurality of component receiving parts are a plurality of recesses formed in the carrier tape, each said recess having an upper opening to receive each said chip component.

8. The chip component packaging apparatus according to claim 7, wherein said upper opening of said recess has a size smaller than the quadrangular shape of each said cover film piece.

9. The chip component packaging apparatus according to claim 5, wherein said gripping part includes a suction nozzle to hold each said chip component.

10. The chip component packaging apparatus according to claim 5, wherein said gripping part includes a plurality of arms and/or claws to hold each said chip component.

11. The chip component packaging apparatus according to claim 1, wherein the chip component loading unit has a gripping part to grip each said chip component and a vertical drive part to move the gripping part upward and downward, and the gripping part serves as the pressing part upon downward movement of the gripping part caused by the vertical drive part.

12. The chip component packaging apparatus according to claim 11 further comprising a mechanism for translating the gripping part over the carrier tape.

13. The chip component packaging apparatus according to claim 1, wherein said plurality of cover film pieces are attached to the cover tape such that the cover film pieces are arranged in a single line at equal intervals in a longitudinal direction of the cover tape.

14. The chip component packaging apparatus according to claim 1, wherein said plurality of cover film pieces are attached to the cover tape such that the cover film pieces are arranged in two lines in a longitudinal direction of the cover tape.

15. A cover tape comprising:
a base tape;
a plurality of cover film pieces sequentially attached to the base tape for sealing a plurality of component receiving parts formed in a carrier tape, respectively, each said cover film piece having a quadrangular shape; and
a plurality of adhesive parts provided on the plurality of cover film pieces, respectively, each said adhesive part extending along three sides of the quadrangular shape of the cover film piece.

16. The cover tape according to claim 15, wherein a width of each said cover film piece is greater than a first sum of a length of each said component receiving part and an interval between two neighboring component receiving parts and is less than a second sum of the first sum and a half of the interval.

17. The cover tape according to claim 15, wherein the adhesive part has adhesive power greater than attachment power of each said cover film piece attached to the base tape.

18. The cover tape according to claim 15, wherein said plurality of component receiving parts are a plurality of recesses formed in the carrier tape, each said recess having an upper opening to receive each said chip component.

19. A chip component packaging method for encapsulating a plurality of chip components in a plurality of chip component receiving parts, respectively, the chip component packaging method comprising:
(A) preparing a cover tape that has a plurality of cover film pieces attached to a lower face of the cover tape, each said cover film piece having an adhesive part;
(B) preparing a carrier tape having the plurality of chip component receiving parts;
(C) feeding the carrier tape such that each of the component receiving parts is located at a predetermined loading position upon each feeding;
(D) loading one of the chip components in a corresponding one of the component receiving parts at the loading position;
(E) feeding the cover tape in a direction intersecting the carrier tape such that one of the cover film pieces of the cover tape faces said corresponding one of the component receiving parts of the carrier tape;
(F) pressing the cover tape to the carrier tape such that said one of the cover film pieces is forced to adhere to the carrier tape to seal said corresponding one of the component receiving parts; and
(G) repeating said (C), (D), (E) and (F).

20. The chip component packaging method according to claim 19, wherein repeating said (F) is carried out such that a portion of one said cover film piece overlaps a corresponding portion of another said cover film piece.
